(19) United States
(12) Patent Application Publication
(10) Pub. No.: US 2025/0138611 A1
(43) Pub. Date: May 1, 2025

(54) METHOD OF MONITORING OPERATING PARAMETERS

(71) Applicant: Arm Limited, Cambridge (GB)

(72) Inventors: Amit Chhabra, Noida (IN); Rainer Herberholz, Great Abington (GB); El Mehdi Boujamaa, Valbonne (FR)

(73) Assignee: Arm Limited, Cambridge (GB)

(21) Appl. No.: 18/925,432

(22) Filed: Oct. 24, 2024

(30) Foreign Application Priority Data
Oct. 27, 2023 (IN) 202311073299
Oct. 27, 2023 (IN) 202311073432
Nov. 24, 2023 (IN) 202311079971
Mar. 20, 2024 (GB) 2403978.6
Mar. 20, 2024 (GB) 2403979.4
Mar. 20, 2024 (GB) 2403984.4

(51) Int. Cl. G06F 1/26

(52) U.S. Cl. CPC G06F 1/26

(57) ABSTRACT

The present techniques relate to monitoring of operating parameters at a circuit and disclose a method comprising: receiving, at a delay monitor from a power delivery network, a voltage signal representative of the voltage level of the voltage; receiving, at the delay monitor from a clock distribution network, a clock signal representative of an output clock of the clock distribution network; periodically generating, at the delay monitor, a measurement value responsive to the voltage signal and the clock signal; adjusting, at the delay monitor, a threshold level for the measurement value from a first threshold to a second threshold, where the second threshold level corresponds to a target voltage level; providing, from the delay monitor to the clock distribution network, a non-violation signal responsive to the measurement value reaching the second threshold.

### TECHNICAL FIELD

The present techniques relate to monitoring of operating parameters at a circuit.

### BACKGROUND OF THE DISCLOSURE

Some computer circuits (e.g., a central processor unit (CPU) or graphics processor unit (GPU)) may require different voltages and clock frequencies during operation to deliver performance with energy efficiency.

For example, there may be circumstances that require an increase or decrease in voltage and/or clock frequency. These increases or decreases are sometimes in response to a change in another of the operating parameters, such as a voltage droop or an over-current alert, or they may be made by choice to tune the performance of the circuit. Whichever the circumstances, monitoring of the operating parameters, such as voltage and/or frequency is helpful in determining the progress of, and controlling the operation of, the changes in operating characteristics of the circuit.

### SUMMARY OF THE DISCLOSURE

The present techniques relate to addressing the monitoring of the operating characteristics of such circuits.

In a first approach there is provided a method of monitoring a voltage to determine when a level of the voltage has reached a target level from an initial level, the method comprising: receiving, at a delay monitor from a power delivery network, a voltage signal representative of the voltage level of the voltage; receiving, at the delay monitor from a clock distribution network, a clock signal representative of an output clock of the clock distribution network; periodically generating, at the delay monitor, a measurement value responsive to the voltage signal and the clock signal; adjusting, at the delay monitor, a threshold level for the measurement value from a first threshold to a second threshold, where the second threshold level corresponds to a target voltage level; providing, from the delay monitor to the clock distribution network, a non-violation signal responsive to the measurement value reaching the second threshold.

The method may further comprise: providing, from the delay monitor to the clock distribution network, a violation signal until the measurement value reaches the second threshold.

The method may further comprise: adjusting at the power delivery network the voltage from the initial level to the target level responsive to instructions from firmware, wherein adjusting, at the delay monitor, a threshold level for the measurement value from the first threshold to the second threshold may comprise: adjusting the threshold level responsive to instructions from firmware.

The method may further comprise: providing, to a first state machine, the non-violation signal or the violation signal to allow the first state machine to control the frequency of one or more clock sources responsive thereto. Periodically generating a measurement value responsive to the voltage signal and the clock signal may comprise: generating the measurement value in accordance with a sample period value, where the sample period duration may be programmable. The sample period may be defined by firmware or defined in registers.

The non-violation signal may be output when the measurement value meets or exceeds the second threshold for the duration of at least one sample period. The method may further comprise: adjusting, at the delay monitor, the threshold level from the second threshold to the first threshold following the non-violation signal, wherein the adjusting the threshold level from the second threshold to the first threshold may comprise: adjusting the threshold level from the second threshold to the first threshold level when the frequency of the output clock is adjusted responsive to the non-violation signal.

The output clock may be adjusted responsive to the first state machine setting properties of one or more clock sources responsive to the non-violation signal, where a first clock source of the one or more clock sources may provide a first nominal clock signal and/or a first fallback clock signal and where a second clock source of the one or more clock sources may provide a second nominal clock signal and/or a second fallback clock signal.

The method may further comprise:/receiving, at the delay monitor from the first or a second state machine, a signal to initiate monitoring the voltage. The first threshold may be lower than the second threshold or the first threshold may be higher than the second threshold

In a further approach there is provided a circuit for monitoring a voltage to determine when a level of the voltage has reached a target level from an initial level, the circuit configured to: receive, from a power delivery network, a voltage signal representative of the voltage level of the voltage; receive, from a clock distribution network, a clock signal representative of an output clock from the clock distribution network; receive, a signal to initiate monitoring the voltage; periodically generate a measurement value responsive to the voltage signal and the clock signal; adjust a threshold level for the measurement value from a first threshold to a second threshold, where the second threshold level corresponds to a target voltage level; provide, to the clock distribution network, a non-violation signal responsive to the measurement value reaching the second threshold.

In a further approach there is provided a processor comprising the above circuitry.

In a further approach there is provided a system comprising: the above circuitry, implemented in at least one packaged chip; at least one system component; and a board, wherein the at least one packaged chip and the at least one system component are assembled on the board.

In a further approach there is provided a chip-containing product comprising the above system assembled on a further board with at least one other product component.

In a further approach there is provided a non-transitory computer-readable medium to store computer-readable code for fabrication of the above circuitry.

The method and circuit according to the present technology may thus be used in adjustment of operating parameters at a circuit, and that method may be realised in the form of a non-transitory computer readable medium comprising a structure of data and imperatives operable to cause a device to construct a set of electronic logic components which, when embedded in an electronic device and activated thereon, cause the electronic device to perform the steps of the method of the present technology as described hereinabove.

As will be clear to one of skill in the art, a hybrid approach may also be taken, in which hardware logic, firmware and/or software may be used in any combination to implement the present technology.

### BRIEF DESCRIPTION OF DRAWINGS

Implementations of the disclosed technology will now be described, by way of example only, with reference to the accompanying drawings, in which:

FIG. 1 schematically shows a diagram of a system having a clock control circuit;

FIG. 2 schematically shows a diagram of a delay monitor of the system of FIG. 1;

FIG. 3 schematically shows a diagram of an example delay line of the delay monitor of FIG. 2;

FIG. 4 schematically shows system level waveforms;

FIG. 5 shows schematically shows a simplified flow diagram of a method of operation of the delay monitor of FIG. 2 according to one implementation of the present techniques;

FIG. 6 schematically shows waveforms and signals of the delay monitor;

FIG. 7 schematically shows a simplified flow diagram of a method of operation of a delay monitor according to an implementation of the present techniques; and

FIG. 8 illustrates a system and a chip-containing product.

### DETAILED DESCRIPTION

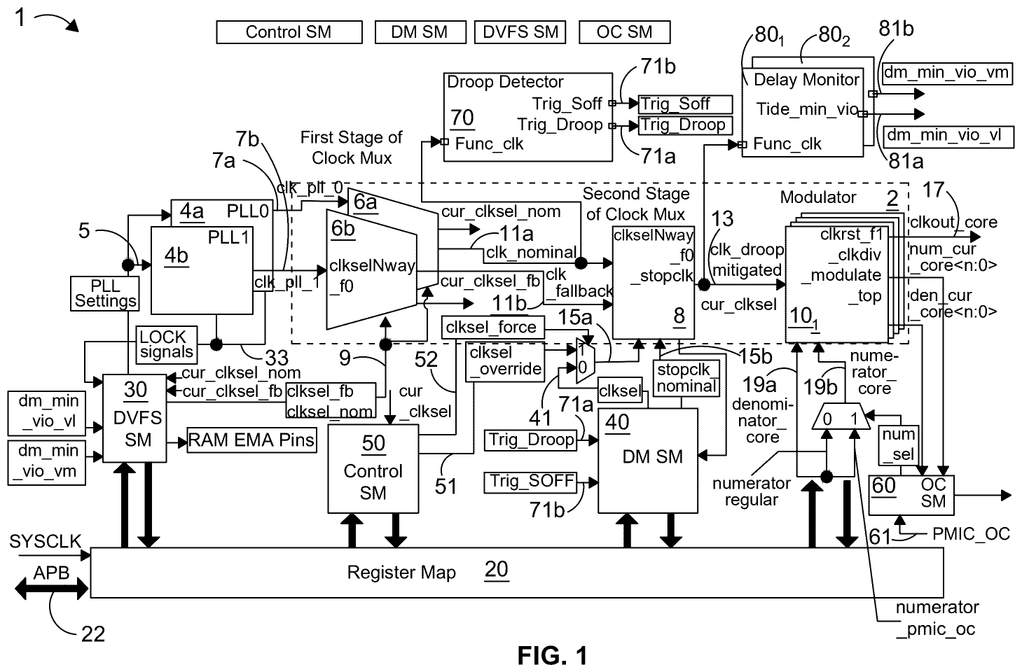

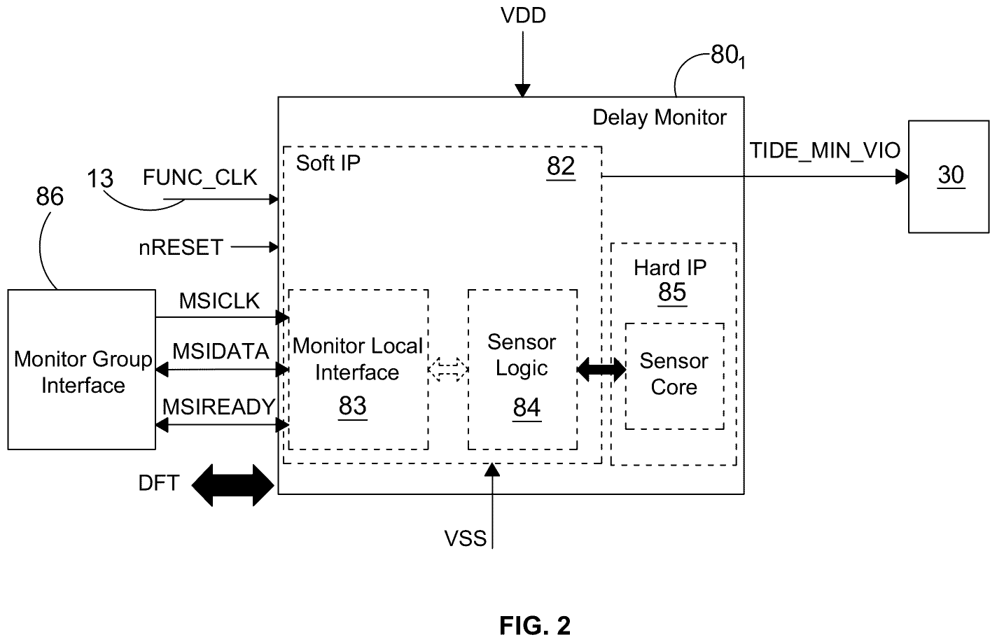

FIG. 1 schematically shows a diagram of a circuit system 1 (e.g., of a system on chip) having a clock control circuit 2 and where FIG. 2 schematically shows features of the clock control circuit 2 in more detail.

It will be appreciated that the term “signal” is non-limiting and may take any form to convey a message, operation, or information to a component (hardware or software), where, for example, the signal may comprise one or more bits, a logic value (e.g., high, or low), or a voltage value etc. In embodiments the signal may comprise a clock signal having a particular frequency and or level (e.g., voltage level).

Furthermore, the signals provided to a component (e.g., hardware or software) to control the operation thereof (E.g., to select a particular clock signal) or to change properties thereof (e.g., to cause the component to operate in a certain way) may be referred to as a “control signal.”

In the present example, the control signals provided to the clock control circuit 2 may be provided from circuitry comprising (e.g., configured to operate as) state machines 30, 40, 50, 60 as will be described in detail below. Furthermore, clock signals may be provided to clock pins of the components of the clock control circuit 2. The clock control circuit 2 and clock sources and other state machines 30, 40, 50, 60 are taken to operate as a clock control state machine (CCSM), and form part of a clock distribution network for generating an output clock signal which may be used by another system (e.g., a CPU or GPU)

The state machines may be implemented as hardware and/or software. In embodiments, the state machines are implemented as fixed function hardware.

The state machines may access, for example, storage to generate the signals to control the clock control circuit 2 (or other state machines) in response to the data/values (e.g., one or more bits) therein. In the present illustrative example, the storage comprises a plurality of registers, where one or more of the registers may be programmable.

The state machines may access (read and/or write) registers of register map 20 as required for a particular operation. The register map 20 may be accessed by components of the system 1.

The registers may also be accessed by, for example, firmware (e.g., during start-up), where the firmware may access the registers, for example, via an interface such as an Advanced Peripheral Bus (APB), which may be part of the Advanced Microcontroller Bus Architecture (AMBA) protocol family, although the claims are not limited in this respect.

Clock control circuit 2 receives a plurality of clock signals from clock sources 4n (where “n” is an integer, n>1), where clock source₀ 4a & clock source₁ 4b, are shown in FIGS. 1-3.

In the present embodiment the clock sources 4a & 4b are phased locked loops (PLL), where each clock source provides a clock signal having a voltage and frequency.

However, the claims are not limited to the clock sources being PLL and in a further embodiment the clock source 4b may be a derivative of clock source 4a. For example, the clock source 4b may be a divided clock of the first clock source 4a. In a still further embodiment, the first and second clock sources 4a & 4b may be fixed clock sources from different units.

In the present embodiment, where the clock sources 4a & 4b are PLLs, each clock source 4a/4b receives one or more PLL signals 5 to configure the properties of the clock signals and supplies the clock signal 7a, 7b to the clock control circuit 2.

In the present illustrative example, a Dynamic Voltage and Frequency Scaling (DVFS) state machine 30 provides the PLL signals 5. The properties of the PLL signals may be set in response to requests from the control state machine 50 dependent, for example, where a request from control state machine may request the DVFS state machine 30 to, for example, perform a set of tasks that are required to configure the PLL in accordance with a DVFS sequence. The DVFS state machine 30 may receive “LOCK signals” from the one or more clock sources 4a & 4b to confirm that the properties of the respective clock signals are configured as expected in response to the one or more PLL signals (e.g., that a required phase lock is achieved).

Furthermore, the control state machine 30 may send requests to the DVFS state machine 30 to increase or decrease a target voltage/operating point (OPP) dependent on an existing OPP (e.g., as defined in one or more registers).

The control state machine 50 may also request the DVFS state machine to perform other tasks such as, for example, to configure a RAM (Random access memory) EMA (extra margin adjustment), where the DVFS state machine 30 drives the EMA related pins of the RAM, and where the RAM pin states are dependent on, for example, the type of bitcell, memory architecture and the voltage of operation.

The clock control circuit 2 comprises a first clock path stage comprising multiplexers 6a, 6b, which are controlled, responsive to clock select signal 9 (depicted as clksel_nom or clksel_fb in FIGS. 1-3), to cause the first stage to supply a first clock signal 11a which is designated as a nominal clock signal (depicted as clk_nominal) and to supply a second clock signal 11b which is designated as a fallback clock signal (depicted as clk_fallback) to a second clock path stage 8.

Although only two clock sources 4a & 4b are depicted in FIG. 1, the claims are not limited in this respect and multiple clock sources may be provided, where each clock source may provide clock signals which may be used for a particular DVFS scheme. As an illustrative example, a first DVFS scheme may use a first nominal clock signal from a first clock source and first fallback clock signal from a second clock source and a second DVFS scheme may use a second nominal clock signal from third clock source and a second fallback clock signal from a fourth clock source, where the frequency of the nominal and fallback clock signals of the first DVFS scheme are different (e.g. higher or lower) than the respective nominal and fallback clock signals of the second DVFS scheme.

The nominal clock signal 11a comprises a relatively high frequency fast clock that may be provided to a processor (e.g., CPU or GPU) sub-system (e.g., core). The fallback clock signal 11a is a relatively low frequency slow clock that may be used when an event (e.g., a droop event) is detected.

In the present illustrative example, the DVFS state machine 30 provides the clock select signal 9 to drive the nominal clock signal or the fallback clock signal to the second clock path stage dependent on, for example, whether an event (e.g., a droop event) is detected. Since the effects of droop are more severe at higher clock frequencies and higher clock voltages, the fallback clock signal, which is to be selected by the clock mux during droop events, has a lower frequency than the nominal clock signal. In an example, the nominal clock signal has a frequency of 3.5 GHZ, and the fallback clock signal has a lower frequency of, for example, 3 GHZ.

The second clock path stage 8 provides a clock signal 13 to a modulator stage, where the modulator stage comprises a plurality of modulator units 10₁-10ₘ (where “m” is an integer)

In the present example the clock signal 13 is provided from the second clock path stage 8 responsive to signals 15a/15b, where the signals 15a/15b may be provided in accordance with a droop mitigation scheme. Such a droop mitigation scheme may mitigate against the negative effects of voltage droop. In this sense, the output of the clock circuit (output clock signal) is taken to be a mitigated clock signal (depicted as clk_droop_mitigated). Thus, it will be seen that the output clock signal corresponds to the clock signals of the DVFS scheme in use, and the properties of the clock signals of the DVFS schemes (e.g., a first DVFS scheme, second DVFS scheme or otherwise) can be configured by the DFVS state machine 30.

In the present illustrative example, the signals 15a/15b are provided by a droop mitigation state machine 40 and a control state machine 50 dependent on the properties of a droop event.

For example, the droop mitigation state machine 40 and control state machine 50 are used to provide a clock control signal 15a to cause the second clock path stage 8 to select and provide the nominal clock signal 11a or the fallback clock signal 11b to the modulator stage as the mitigated clock signal 13. For example, the droop mitigation state machine 40 is to provide a “clksel” signal 41 which is to cause the second stage 8 to provide either the nominal clock signal 11a or the fallback clock signal 11b to the modulator stage depending on the value of the “clksel” signal 41, and where the control state machine 50 is to provide a “clksel_override” signal 51 which is to override the clksel signal 41, where one of the clksel signal 41 or clksel_override 51 are selected in response to a clksel_force signal 52, which in the present illustrative example is used to control a multiplexer to select between the signals 41 and 51.

Furthermore, the droop mitigation state machine 40 is to provide signal 15b to prevent any clock signal to be provided to the modulator stage on detection and for the duration of a particular event (e.g., a droop event).

The modulator units 10₁-10ₘ each modulate the mitigated clock signal 13 (e.g., using average power modulation) and provide, responsive to modulator signals 19a/19b the modulated clock signal 17 to a particular sub-system as an output clock signal (e.g., to a core (not shown)) of a processor unit (not shown).

The modulator units 10₁-10ₘ may operate independently of each other, so as to, for example, independently provide average power modulation per core of a multi-core system. In the present illustrative example, the clock control circuit 2 comprises a modulator unit 10ₘ per core (not shown))

The modulator units 10₁-10ₘ may be individually selected and/or the settings thereof may be controlled responsive to modulator control signals (hereafter “modulator signal(s)”, “control signal” or “signal(s)”). The modulator signals 19a/19b may be used to select the modulator unit 10₁ to 10ₘ which is used to modulate the mitigated clock signal 13 and/or to identify the sub-system to which the clock signal 17 is to be provided. The modulator signals 19a/19b may also define how the modulator is to modulate the mitigated clock signal 13. In the present illustrative example, the modulator signal 19a comprises a denominator value which may be obtained from a register (e.g., via register map 20). The modulator signal 19b comprises a numerator value (e.g., depicted as numerator_regular or numerator_pmic_oc), which may be obtained from registers. In the present illustrative embodiment, the fraction of clock pulses present in the output clock signal 17 relative to the mitigated clock signal 13 are taken to be the numerator/denominator.

The values of the numerator and denominator can be programmed independently for each modulator unit and stored in the programmable register(s) of register map 20 where the modulator uses to the numerator and denominator values to modify the mitigated clock signal 13 (e.g., to change the frequency) to provide the output clock signal 17.

In the present illustrative example, modulator signal 19b may be selected to be numerator_pmic_oc by an over-current state machine 60, where the over-current state machine 60 provides hardware support for current demand reduction, for example, in the case of a signal 61 (e.g., a warning signal (e.g., a pre-over-current signal)) from a Power Management IC (PMIC) (not shown in FIG. 1).

As an illustrative example, the over-current state machine 60 receives warning signal 61 and asserts modulator signal 19b to be ‘numerator_pmic_oc’ as opposed to ‘numerator_regular’ when the warning signal 61 is received from the power management PMIC, where the numerator_pmic_oc value changes the modulator settings to provide a modulated clock signal 17 which reduces the current demand by a sub-system (not-shown) receiving the modulated clock signal 17 in comparison to ‘numerator_regular’ value for the numerator.

In embodiments the modulator units 10₁-10ₘ may not alter the clock frequency of the mitigated clock signal 13, but may supress some of the clock pulses e.g., to reduce the current demand of the sub-system.

As described above the state machines 30, 40, 50 and/or 60 may access values/data in registers of register map 20 to generate the control signals to control the clock control circuit 2 (or other state machines) in response to the data/values (e.g., one or more bits) therein.

In embodiments the PMIC may be used to set the voltage (VDD) provided to one or more sub-systems (e.g., a processor unit) from a power delivery network (not shown).

The properties (e.g., level) of the voltage (VDD) provided to the sub-system(s) may be controlled by the PMIC in response to instructions e.g., from firmware (e.g., running on the system control processor (SCP)). As in an illustrative example, the level of the VDD may be required to be relatively high when the output clock signal 17 corresponds to a relatively high frequency (e.g., a frequency of a nominal clock signal of a first DVFS scheme) and can be reduced when the output clock signal corresponds to a relatively low frequency (e.g., a frequency of a nominal clock signal of a second DVFS scheme).

In the present illustrative example, values/data in registers of the register map 20 can be used to configure the settings of state machines in the programmable registers.

Examples what the data/values in the registers in the present illustrative embodiments include, but are not limited, to define:
architectural level inputs for the nominal PLL (or clock source);
a bit(s) for enabling the nominal PLL (or clock source);
settings for the clock generator that drives the frequency of a nominal clock signal and/or the frequency of a fallback clock signal;
architectural level inputs for the fallback PLL (or clock source);
a bit(s) for enabling the fallback PLL (or clock source);
the settings for the clock generator that drives the fallback frequency;
timer that runs on SYSCLK. It is used to ascertain voltage stability for both the memory and the logic supply;
a strategy that CCSM uses to determine voltage stability;
a strategy for droop mitigation;
whether a mitigation strategy is enabled;
the mitigation strategy on a droop event;
overrides the existing droop mitigation of stopping the clock during a DVFS transition;
the settings of the Modulator;
the value of the denominator of the Modulator;
the value of the numerator of the Modulator in regular use case;
the value of the numerator of the Modulator when there is a pre-over-current warning from the PMIC;

It will be appreciated that the above examples of data/values in the registers are not exhaustive and are for illustrative purposes only.

As described above, the various state machines 30, 40, 50, 60 may interact and influence the control and/or clock signals generated by one another.

Additionally, or alternatively, the system 1 may comprise further components (hardware and/or software components) that may interface with the various state machines 30, 40, 50, 60 and vice versa to influence the control and/or clock signals generated thereby. For example, the various state machines of the CCSM may interface with droop detectors or delay monitors to carry out droop mitigation and DVFS.

As an illustrative example, system 1 comprises one or more delay monitors 80, two of which 80₁ & 80₂ are depicted in FIG. 1. The delay monitors 80 may be located in different locations of a processor (e.g., CPU or GPU), or even outside the physical perimeter of a processor (e.g., CPU or GPU), with each delay monitor to measure the delays e.g., in a clock cycle of a clock supplied to components at the respective locations from a clock distribution network.

In response to an event (e.g., a delay in the clock signal at the monitored location vs an expected delay), a delay monitor that detects the event generates an alert (or violation) signal, where delay monitor 80₁ generates an alert signal 81a and delay monitor 802 generates alert signal 81b. In the present illustrative example of FIG. 1, the alert signal 81a (depicted as (dm_min_vio_vl in FIG. 1) comprises a delay monitor alert signal for a logic supply being monitored and the alert signal 82a depicted as (dm_min_vio_vm in FIG. 1) comprises a delay monitor alert signal for a memory bitcell supply being monitored. However, it will be appreciated that the claims are not limited in this respect, and delay monitors may be provided to generate alert signals for many different areas of a processor (e.g., CPU/GPU sub-system).

The alert signals may be used as inputs to DVFS state machine 30 to, for example, calibrate DVFS setpoints, manage DVFS transitions and/or to allow the DVFS state machine to check for voltage stability while performing transitions.

Looking now in more detail at the delay monitors, delay monitor 80₁ is schematically shown in the high-level diagram of FIG. 2, and comprises soft IP, which in the present illustrative example, comprises a local interface 83 and sensor logic 84.

The soft IP outputs (to DVFS SM in the present illustrative embodiment) an alert (e.g., violation or non-violation) signal TIDE_MIN_VIO which is indicative of the stability of VDD. In embodiments TIDE_MIN_VIO may be synchronous with the nominal clock signal 13. TIDE_MIN_VIO will be described in further detail below.

The delay monitor also comprises hard IP 85, which in the present illustrative example comprises a sensor core 85, which may be tied, for example, to the monitored location's (e.g., CPU/GPU) logic voltage supply before any power gates at the architectural level.

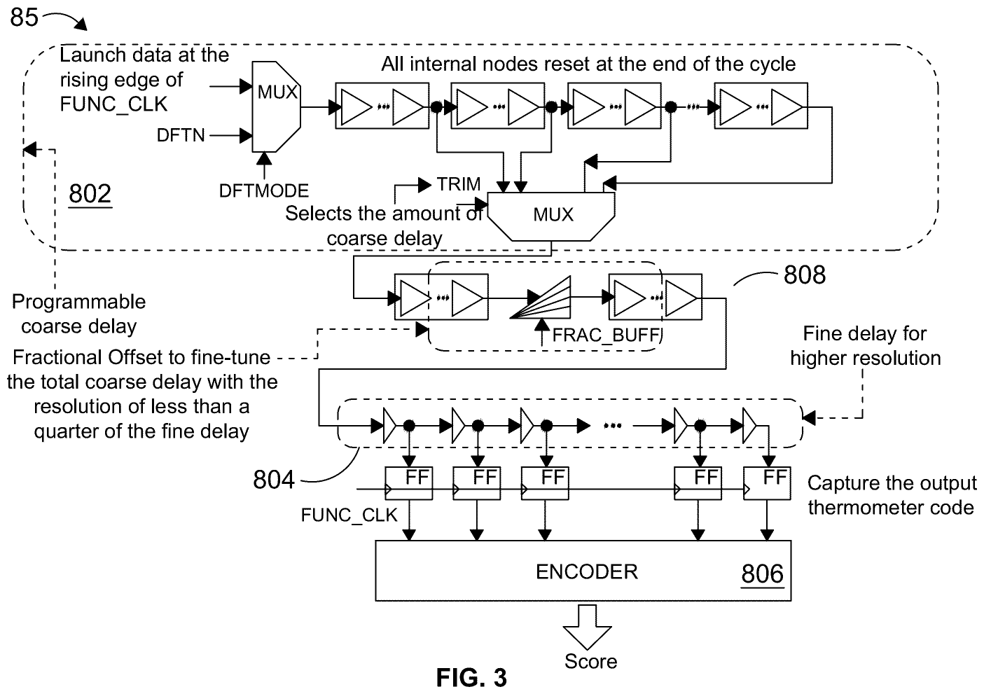

The sensor core 85 may comprise one or more delay lines connected to a particular area of the sub-system (e.g., a top metal or bottom metal area) to measure delays in that particular area and output a measurement value or score (hereafter “measurement value”). An example of the delay lines used by sensor core 85 is depicted in FIG. 3.

A monitor group interface 86 may provide communications between the local interfaces of the respective delay monitors 80n and may send/receive signals to/from each of the local interfaces 83. Each of the delay monitors may be activated independently of each other.

In operation, the delay monitor 80₁ quantifies a delay within a clock cycle and generates one or more measurement values related to the quantified delay, and may generate one or more alert signals (e.g., violation or non-violation signals) responsive to the one or more measurement values.

An example of the sensor core 85 which may be used in accordance with the present techniques is illustratively shown in FIG. 3. It will be appreciated that the delay lines are only provided as an illustrative example and the claims are not limited to the delay lines of FIG. 3.

The sensor core 85 comprises a coarse delay line 802, a fine delay line 804 and an encoder 806. The delay monitor optionally comprises a fractional offset 808 between the coarse delay and the fine delay.

The delay monitor works on the principle of a delay line that captures the delay traversed by a set of gates in each FUNC_CLK cycle.

The coarse delay line 802 is programmable (e.g., by software) to allow flexibility in the obtained value of a measurement value, where the amount of delay contributed by the course delay line 802 can be adjusted using TRIM bits. If TRIM=0′×00, then only a minimum fixed delay is present. As the value of TRIM increases, the amount of the delay from the course delay line 802 increases and hence the value of the measurement value will reduce.

A measurement value is provided by the output of the encoder where the measurement value corresponds to a count of the number of fine gate stages traversed in the fine delay line 804 during a predetermined number of clock cycles. The output may be measured every output clock cycle (e.g., FUNC_CLK) of a clock distribution network and averaged over a predetermined number of clock cycles for analysis.

In operation, the sensor core of the Hard IP 85 captures this value for each FUNC_CLK cycle when the Delay Monitor 80 is active. This n-bit value is then processed by the sensor logic 84 and one or more alert signals provided as the output.

The sensor logic 84 may process the measurement value to build statistical information or data, hereafter “tides.” The tides can then be used to check that the system 1 (or portions thereof) are operating as expected, and to cause an alert signal when any unexpected or undesired operation is detected.

As an illustrative example, AVAL_MIN_SCORE may be taken to be a minimum threshold of the measurement value, and when the actual measurement value monitored by delay monitor (DMON_SCORE) falls below (or above, in other embodiments) the AVAL_MIN_SCORE, the delay monitor may generate an alert signal (e.g., TIDE_MIN_VIO). In embodiments, firmware (e.g., running on the SCP) may set the value of the AVAL_MIN_SCORE.

It will be appreciated that the delay line 804 is only provided as an example of method to provide the measurement value.

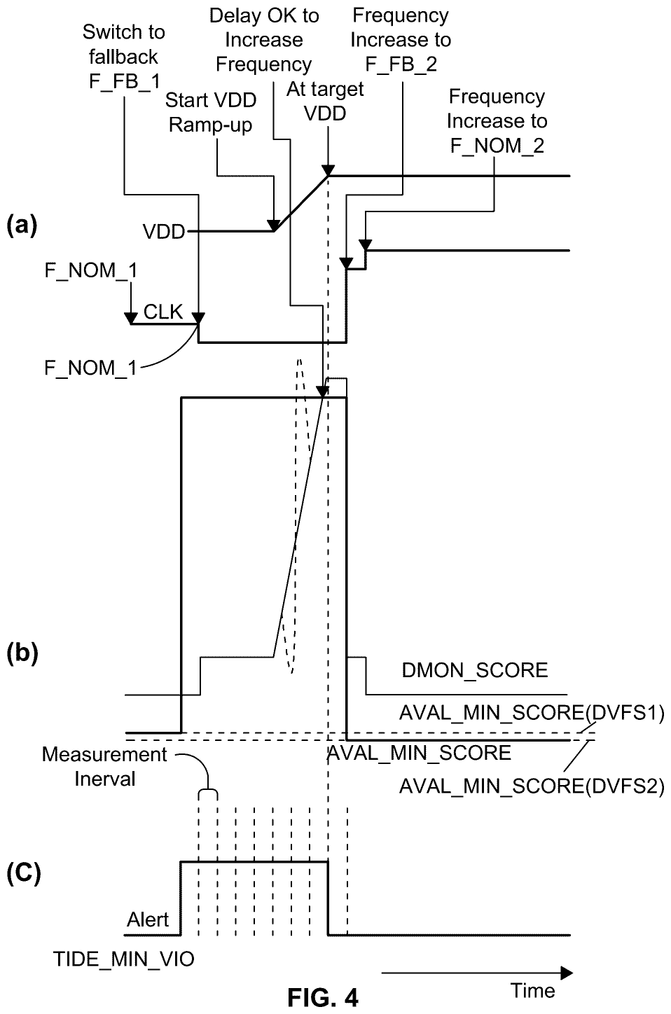

As an illustrative example FIG. 4 schematically shows system level waveforms (a)-(c).

FIG. 4 (a) illustratively shows waveforms of voltage (VDD) of the monitored location to which the delay monitor is tied (e.g., as set by the PMIC) and the frequency of the CLK signal (e.g., which corresponds to the mitigated clock signal (shown as mitigated clock signal 13 in FIG. 1)).

As above, the properties of the AVAL_MIN_SCORE of FIG. 4 (b) may be set by firmware and the DMON_SCORE corresponds to the measurement value generated at the delay monitor.

In the present illustrative example, DMON_SCORE changes based on or in response to changes in the VDD or CLK waveforms of FIG. 4 (a).

For example, when the clock frequency is reduced (e.g., switching from a first nominal clock signal F_NOM_1 to a first fallback signal F_FB_1) the DMON_SCORE increases (e.g., due to a higher clock period). The measurement value also increases as VDD ramps up and stabilises when VVD reaches the “target VDD”. There is a reduction in DMON_SCORE as the system clock increases to that of a second fallback clock signal F_FB_2 (e.g., due to a lower clock period), and the DMON_SCORE decreases further when the system clock changes to that of a second nominal clock signal F_NOM_2 having a higher frequency than F_FB_2.

The delay monitor will issue an alert (or violation) signal having a particular level or value (depicted as TIDE_MIN_VIO asserted as a high logic level) when DMON_SCORE is lower than the threshold AVAL_MIN_SCORE (as depicted in FIG. 4 (c)) for a pre-specified measurement period (as depicted by the interval between two successive dotted lines in FIG. 4 (c)).

Thus, setting AVAL_MIN_SCORE at (or substantially at) the level of the DMON_SCORE when at the target VDD, it's possible to determine (or detect) when the VDD reaches a desired (or target) level as the alert signal TIDE_MIN_VIO will be asserted as a non-violation signal which is at a different value or level (e.g. low logic level) to that when the measurement value is higher than or equal to the threshold. Thus, VDD is taken to be stable or at an established level when TIDE_MIN_VIO is at a low logic level or 0 or the like. When VDD is taken to be established the threshold AVAL_MIN_SCORE is reduced to the AVAL_MIN_SCORE specific for the properties of particular clock source.

As with the violation signal above, the delay monitor may issue the non-violation signal when DMON_SCORE is higher than the threshold AVAL_MIN_SCORE (as depicted in FIG. 4 (c)) for a sample period or measurement period (here after “sample period” as depicted by the interval between two successive dotted lines in FIG. 4 (c)).

In embodiments, the length of the measurement period may be programmable (e.g. defined by firmware or stored in one or more registers), where the length of the sample period is specified to avoid or mitigate the effects of transient events which may cause a false overshoot of DMON_SCORE (e.g. where DMON_SCORE reaches the desired (or target) level responsive to a transient VDD event). Such functionality means that DMON_SCORE will be at or beyond the threshold for at least the specified sample period of time before VDD is taken to be established.

As above, the properties of AVAL_MIN_SCORE may be set by firmware and, when an increase in VDD is required, the AVAL_MIN_SCORE is increased before the clock frequency and the VDD change.

Similarly, the clock frequency may be reduced prior to the VDD increase.

When the clock frequency is reduced and the AVAL_MIN_SCORE is increased to correspond with the VDD target, the delay monitor may sample the measurement value at a specified sample period, such that TIDE_MIN_VIO would be low if for the entire measurement duration there was no violation (i.e. the DMON_SCORE>=AVAL_MIN_SCORE) and high when a violation is detected in any cycle within the entire measurement duration (i.e. when DMON_SCORE<AVAL_MIN_SCORE).

DVFS SM sets the properties of the nominal clock signal(s) and fallback clock signal(s), and thus the properties of the output clock signal. The DFVS SM also monitors the TIDE_MIN_VIO, such that when the VDD is taken to be stabilised the DFVS can increase the frequency of the clock signals from the PLLs thereby resulting in an increased signal for mitigated clock signal provided to the sub-system.

As an illustrative example, and looking at the VDD waveform at FIG. 4 (a), the voltage at the “Start VDD ramp-up” may be taken to be 0.6V and the voltage “At target VDD” may be taken to be 0.9V. Looking at the CLK signal at FIG. 4 (a), the frequency at F_NOM_1 may be taken to be 1 GHZ and the frequency at F_NOM_2 may be taken to be 3 GHZ, where 3 GHZ is only used when the VDD voltage is at 0.9V. Thus, the DVFS SM may control the properties of the PLL such that an output clock signal of 3 GHz is only available when the VDD is stabilised at the target 0.9V.

Such a change in frequency may be required by, for example, an application (e.g., a graphics application) running on a sub-system (e.g., GPU) which requires an increased frequency. For example, when a GPU running with an output clock from a first DVFS scheme (e.g. where a first clock source provides a first nominal clock having a first nominal frequency or a first fallback clock having a first fallback frequency) requires a higher frequency for an application running thereon, the clock distribution network (comprising the CCSM) may switch from the first DVFS scheme to a second DVFS scheme (e.g. where a second clock source provides a second nominal clock having a second nominal frequency or a second fallback clock having a second fallback frequency). The GPU may require a higher voltage before running with the second DVFS scheme.

However, changing the circuit voltage VDD from a first level VDD0 (e.g., 0.6V) to target, second level, VDD1 (e.g., 0.9V) may result in voltage or current transients which may result in poor performance (e.g. damage, timing failure etc.) in the circuit. On the other hand, ramping the circuit voltage to the target level at a lower clock frequency, can reduce or mitigate such risks. Further, it is desirable to switch to the second DFVS scheme when the voltage is at the higher voltage.

Therefore, to change the frequency in a safe manner, the DVFS state machine changes the clock frequency from the initial nominal clock frequency F_NOM_1 to an initial fallback clock frequency F_FB_1. Once the clock frequency is lowered to the initial fallback clock frequency F_FB_1 then the voltage VDD is ramped, e.g., in response to control instructions from the PMIC, from the first level VDD0 to the target level VDD1. The firmware may also instruct the delay monitor to begin a monitoring action, and to set the appropriate threshold (AVAL_MIN_SCORE) to be at the level of a target voltage to enable monitoring of the voltage level to detect when the target level is reached.

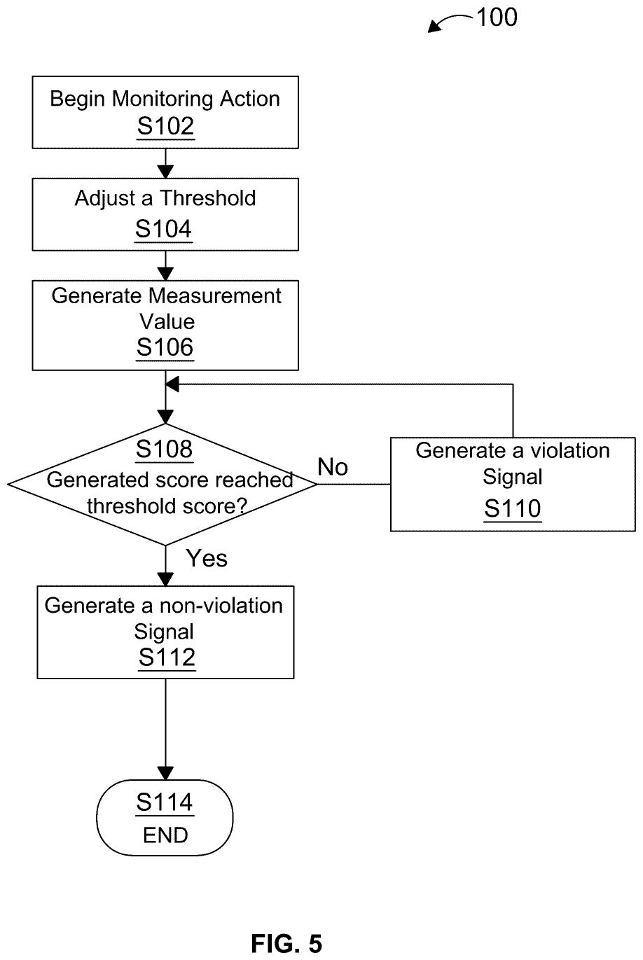

FIG. 5 schematically shows a simplified flow diagram of a method of operation 100 of the delay monitor of FIG. 2 according to one implementation of the present techniques.

At S102 the delay monitor receives, for example, from firmware, an instruction to begin a monitoring action or procedure. The monitoring action, which in the present illustrative example, may be required because a sub-system (e.g., a CPU or GPU) requires a clock signal with a higher frequency and, thus, requires an increased voltage (VDD). Such a change in frequency may be required because, for example, an application (e.g., a graphics application) running on the sub-system requires a higher frequency clock.

At S104 the delay monitor receives (e.g., from firmware) an instruction to set the appropriate threshold (AVAL_MIN_SCORE) to be at the level of a target voltage. A PMIC may also receive (e.g., from firmware) an instruction to increase the voltage (VDD) from a first level to a target level and instructs a power delivery network accordingly.

At S106 the delay monitor generates a measurement value which is based on or is in response to the voltage level from the power delivery network and/or the clock frequency received from the clock distribution network.

At S108 the measurement value is periodically sampled and checked as to whether it reaches the threshold.

At S110, when the threshold is not reached, an alert (violation) signal is generated.

At S112, when the threshold is reached, an alert (non-violation) signal is generated to signify that the target voltage has been reached. In the present illustrative embodiment, the non-violation signal is output to the DVFS state machine (as shown in FIG. 1). At S114 the process ends.

The method 100 provides for monitoring one or more operating parameters (e.g., voltage/frequency) such that it can be determined when a target operating parameter (e.g., VDD) has been reached. The method 100 can be employed when adjusting the voltage and/or clock frequency of one or more circuits.

As above, in the example of FIG. 4, the measurement value output by the delay monitor is responsive to the VDD of the power delivery network and the frequency of the output clock signal of the clock distribution network. The threshold measurement value AVAL_MIN_SCORE may be set to correspond to a level which DMON_SCORE will reach when the voltage VDD reaches the target level VDD1. In other embodiments, the threshold measurement value AVAL_MIN_SCORE corresponds to a minimum acceptable level that is within a tolerance range of the target level VDD1. For example, the tolerance range may be 5% of VDD1, meaning that when the voltage VDD reaches the target voltage, AVAL_MIN_SCORE will be at approx. 95% of DMON_SCORE. As will be appreciated, the threshold minimum score may be set to any suitable value, such as 90%-100% of DMON_SCORE VDD1 when the voltage VDD reaches the target voltage.

After generating the alert (violation) signal at step 110, the method 100 may comprise waiting for a predetermined length of time (e.g., 10-200 clock cycles) before sampling the measurement value to check if the threshold measurement value was reached.

The alert signal may be provided to a DVFS state machine, where when the DVFS state machine receives an alert (non-violation) signal, it may change DVFS scheme and/or the properties of one or more clock sources (as depicted in FIG. 1).

For example, as shown in FIG. 4, when the target voltage level is reached (VDD1 in FIG. 4) and an alert (non-violation) signal is received from the delay module, the DVFS state machine changes the DVFS scheme such that the clock frequency is that of second fallback clock frequency F_FB_2 and then subsequently changes the clock frequency to be that of second nominal clock frequency F_NOM_2.

In embodiments, the alert signal (violation/non-violation signal) is generated when the threshold is reached for the duration of a sample period, where the sample period may be programmable. The length of the sample period may be specified to avoid or mitigate the effects of transient events which may cause a false overshoot of the threshold.

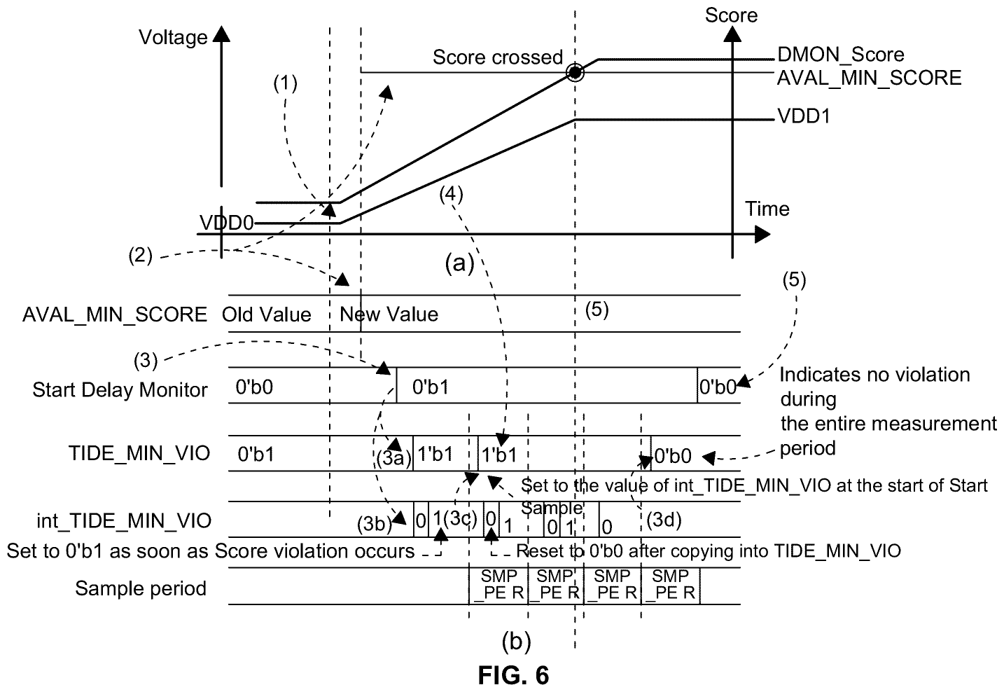

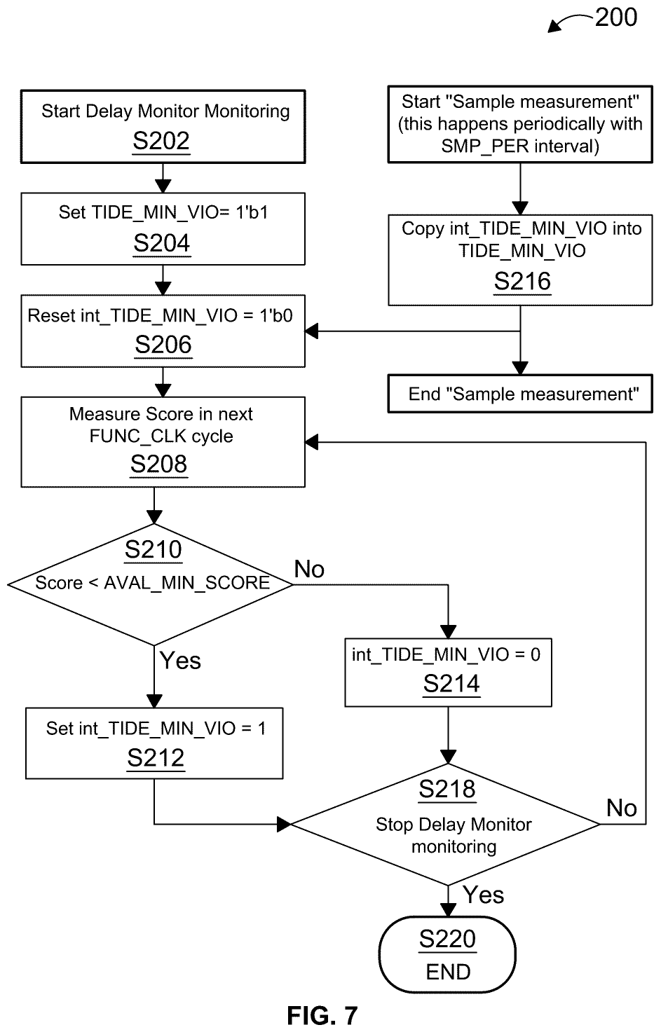

FIG. 6 (a) schematically shows a waveform and FIG. 6 (b) schematically various signals of the delay monitor in accordance with an embodiment; and FIG. 7 schematically shows a simplified flow diagram of the operation of the delay monitor in accordance with the signals.

At FIG. 6 (1) a new voltage setting (e.g., VDD1) is required, and PMIC receives (e.g., from firmware) an instruction to change the voltage from VDD0 to VDD1.

The delay monitor receives (e.g., from firmware) an instruction (or command) to set the appropriate threshold (AVAL_MIN_SCORE) to be at a level corresponding to the target voltage, and at FIG. 6 (2) sets the threshold accordingly in accordance with the instruction.

At FIG. 6 (3) and FIG. 7 S102, the delay monitor starts a monitoring process with a desired value of SMP_PER (sample period) which defines a periodicity of measurement for generating/sampling the measurement value (DMON_SCORE). When the delay monitor starts the monitoring process, the value of TIDE_MIN_VIO is set to 1′b1 (See FIG. 6 (3a) and FIG. 7 S204).

The delay monitor comprises an internal alert signal depicted as int_TIDE_MIN_VIO. The internal alert signal is high or 1 when the measurement value is less than AVAL_MIN_SCORE. The internal alert signal is low or 0 when the measurement value is equal to or greater than AVAL_MIN_SCORE.

The internal alert signal is reset to 0 at the start of each sample period (See FIG. 6 (3b) and FIG. 7 S206) and the measurement value generated during the sample period (See FIG. 7 S208), The sampled measurement value is compared to threshold (See FIG. 7 S210) such that when a violation is detected during the sample period (i.e. where DMON_SCORE<AVAL_MIN_SCORE) then the internal alert signal is set to high or 1 (See FIG. 7 S212). When a violation is detected during the sample period then the internal alert signal is maintained low or 0 (See FIG. 7 S214)

As depicted at FIGS. 6 (3c & 3d) and FIG. 7 S216, the value of alert signal TIDE_MIN_VIO is set to the value of the internal alert signal int_TIDE_MIN_VIO at the end of the previous sample period. For example, in FIG. 6 the TIDE_MIN_VIO signal is initialized to 1′b1 when the delay monitor starts the monitoring process and the TIDE_MIN_VIO signal is updated to take the value of int_TIDE_MIN_VIO (see FIG. 6 (3c)), where a violation was detected during the previous sample period so the value of int_TIDE_MIN_VIO signal at 3c was 1 (1′b1)

Similarly, the TIDE_MIN_VIO signal is updated to take the value of int_TIDE_MIN_VIO (see FIG. 6 (3d)), where no violation was detected during the previous sample period so the value of int_TIDE_MIN_VIO signal at 3d was set to 0′b0)

Thus, when no violation of AVAL_MIN_SCORE is detected during an entire period defined by SMP_PER, the new voltage level is taken to be established for the duration of the sample period and can be taken to be substantially stable at the target level.

At FIG. 6 (5) and FIG. 7 S218, the delay monitor stops the monitoring process, and at FIG. 7 S220, the process ends.

The functionality described above provides a delay monitor which performs a monitoring process to determine when a voltage (e.g., a VDD supplied to a processor (e.g., CPU/GPU)) reaches a specified target level.

The delay monitor can provide an alert signal to a state machine (e.g., the DVFS state machine), which can in turn set the properties of one or more clock sources responsive to the alert signal and enable the clock sources to be provided as an output signal from a clock distribution network.

For example, and looking again at FIG. 1, the DVFS state machine may only cause a clock signal from a particular clock source to be provided to the second clock path stage 8 only when, for example via the “LOCK signals 33”, the settings of the respective clock sources 4a, 4b are confirmed to be correct (e.g. that the one or more clock sources have been correctly configured using the PLL signals 5) and when, via the alert signal TIDE_MIN_VIO, that a target VDD has been established.

Whilst the illustrative examples described above describe the alert signal TIDE_MIN_VIO being low or 0 when no violation is detected, the claims are not limited in this respect and in other embodiments the techniques may be implemented where the alert signal TIDE_MIN_VIO is high or 1 when no violation is detected.

Similarly, the illustrative examples described above generally describe the alert (violation) signal being generated when the measurement value increases to be greater (and/or equal to) the threshold measurement value. However, the claims are not limited in this respect, and it's envisaged that the techniques may be implemented where the measurement value decreases to be less (and/or equal to) the threshold measurement value.

Similarly, the illustrative examples above generally describe the target voltage to be greater or higher than an initial voltage. However, the claims are not limited in this respect, and it's envisaged that the techniques may be implemented where a target voltage is less than or lower than the initial voltage e.g., where it's required to reduce VDD to a lower target VDD.

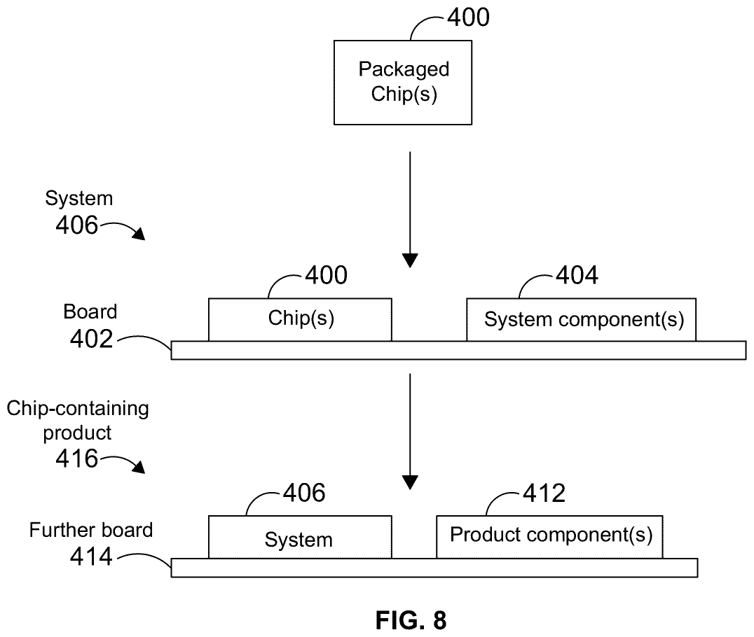

As shown in FIG. 8, one or more packaged chips 400, with the circuitry described above implemented on one chip or distributed over two or more of the chips, are manufactured by a semiconductor chip manufacturer. In some examples, the chip product 400 made by the semiconductor chip manufacturer may be provided as a semiconductor package which comprises a protective casing (e.g. made of metal, plastic, glass or ceramic) containing the semiconductor devices implementing the circuitry described above and connectors, such as lands, balls or pins, for connecting the semiconductor devices to an external environment. Where more than one chip 400 is provided, these could be provided as separate integrated circuits (provided as separate packages), or could be packaged by the semiconductor provider into a multi-chip semiconductor package (e.g. using an interposer, or by using three-dimensional integration to provide a multi-layer chip product comprising two or more vertically stacked integrated circuit layers).

In some examples, a collection of chiplets (i.e., small modular chips with particular functionality) may itself be referred to as a chip. A chiplet may be packaged individually in a semiconductor package and/or together with other chiplets into a multi-chiplet semiconductor package (e.g., using an interposer, or by using three-dimensional integration to provide a multi-layer chiplet product comprising two or more vertically stacked integrated circuit layers).

The one or more packaged chips 400 are assembled on a board 402 together with at least one system component 404 to provide a system 406. For example, the board may comprise a printed circuit board. The board substrate may be made of any of a variety of materials, e.g., plastic, glass, ceramic, or a flexible substrate material such as paper, plastic, or textile material. The at least one system component 404 comprise one or more external components which are not part of the one or more packaged chip(s) 400. For example, the at least one system component 404 could include, for example, any one or more of the following: another packaged chip (e.g. provided by a different manufacturer or produced on a different process node), an interface module, a resistor, a capacitor, an inductor, a transformer, a diode, a transistor and/or a sensor.

A chip-containing product 416 is manufactured comprising the system 406 (including the board 402, the one or more chips 400 and the at least one system component 404) and one or more product components 412. The product components 412 comprise one or more further components which are not part of the system 406. As a non-exhaustive list of examples, the one or more product components 412 could include a user input/output device such as a keypad, touch screen, microphone, loudspeaker, display screen, haptic device, etc.; a wireless communication transmitter/receiver; a sensor; an actuator for actuating mechanical motion; a thermal control device; a further packaged chip; an interface module; a resistor; a capacitor; an inductor; a transformer; a diode; and/or a transistor. The system 406 and one or more product components 412 may be assembled on to a further board 414.

The board 402 or the further board 414 may be provided on or within a device housing or other structural support (e.g., a frame or blade) to provide a product which can be handled by a user and/or is intended for operational use by a person or company.

The system 406 or the chip-containing product 416 may be at least one of: an end-user product, a machine, a medical device, a computing or telecommunications infrastructure product, or an automation control system. For example, as a non-exhaustive list of examples, the chip-containing product could be any of the following: a telecommunications device, a mobile phone, a tablet, a laptop, a computer, a server (e.g. a rack server or blade server), an infrastructure device, networking equipment, a vehicle or other automotive product, industrial machinery, consumer device, smart card, credit card, smart glasses, avionics device, robotics device, camera, television, smart television, DVD players, set top box, wearable device, domestic appliance, smart meter, medical device, heating/lighting control device, sensor, and/or a control system for controlling public infrastructure equipment such as smart motorway or traffic lights.

As will be appreciated by one skilled in the art, the present technology may be embodied as a method, a circuit or a computer readable medium comprising data and imperatives to cause construction of a circuit. Accordingly, the present techniques may take the form of an entirely hardware embodiment, an entirely software embodiment, or an embodiment combining software and hardware. Where the word “component” is used, it will be understood by one of ordinary skill in the art to refer to any portion of any of the above embodiments.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and System Verilog or other behavioural representations of the concepts that can be interpreted by a computer to enable simulation, functional and/or formal verification, and testing of the concepts.

Additionally, or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the present techniques. Alternatively, or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the present techniques. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

In the present application, the words “configured to . . . ” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

In the present application, lists of features preceded with the phrase “at least one of” mean that any one or more of those features can be provided either individually or in combination. For example, “at least one of: [A], [B] and [C]” encompasses any of the following options: A alone (without B or C), B alone (without A or C), C alone (without A or B), A and B in combination (without C), A and C in combination (without B), B and C in combination (without A), or A, B and C in combination.

Although illustrative embodiments of the present techniques have been described in detail herein with reference to the accompanying drawings, it is to be understood that the present techniques are not limited to those precise embodiments, and that various changes and modifications can be effected therein by one skilled in the art without departing from the scope of the present techniques as defined by the appended claims.

1. A method of monitoring a voltage to determine when a level of the voltage has reached a target level from an initial level, the method comprising:
receiving, at a delay monitor from a power delivery network, a voltage signal representative of the voltage level of the voltage;
receiving, at the delay monitor from a clock distribution network, a clock signal representative of an output clock of the clock distribution network;
periodically generating, at the delay monitor, a measurement value responsive to the voltage signal and the clock signal;
adjusting, at the delay monitor, a threshold level for the measurement value from a first threshold to a second threshold, where the second threshold level corresponds to a target voltage level;
providing, from the delay monitor to the clock distribution network, a non-violation signal responsive to the measurement value reaching the second threshold.

2. The method of claim 1 further comprising: providing, from the delay monitor to the clock distribution network, a violation signal until the measurement value reaches the second threshold.

3. The method of claim 1, further comprising: adjusting at the power delivery network the voltage from the initial level to the target level responsive to instructions from firmware.

4. The method of claim 1, wherein adjusting, at the delay monitor, a threshold level for the measurement value from the first threshold to the second threshold comprises:
adjusting the threshold level responsive to instructions from firmware.

5. The method of claim 2, further comprising providing, to a first state machine, the non-violation signal or the violation signal to allow the first state machine to control the frequency of one or more clock sources responsive thereto.

6. The method of claim 1, where periodically generating a measurement value responsive to the voltage signal and the clock signal comprises:
generating the measurement value in accordance with a sample period value.

7. The method of claim 6, where the sample period duration is programmable.

8. The method of claim 6, where the sample period is defined by firmware or defined in registers.

9. The method of claim 6, where the non-violation signal is output when the measurement value meets or exceeds the second threshold for the duration of at least one sample period.

10. The method of claim 1, further comprising:
adjusting, at the delay monitor, the threshold level from the second threshold to the first threshold following the non-violation signal.

11. The method of claim 10, wherein the adjusting the threshold level from the second threshold to the first threshold comprises:
adjusting the threshold level from the second threshold to the first threshold level when the frequency of the output clock is adjusted responsive to the non-violation signal.

12. The method of claim 11, where the output clock is adjusted responsive to the first state machine setting properties of one or more clock sources responsive to the non-violation signal.

13. The method of claim 11, further comprising:
receiving, at the delay monitor from the first or a second state machine, a signal to initiate monitoring the voltage.

14. The method of claim 1, where the first threshold is lower than the second threshold or where the first threshold is higher than the second threshold.

15. A circuit for monitoring a voltage to determine when a level of the voltage has reached a target level, the circuit configured to:
receive, from a power delivery network, a voltage signal representative of the voltage level of the voltage;
receive, from a clock distribution network, a clock signal representative of an output clock from the clock distribution network;
receive, a signal to initiate monitoring the voltage;
periodically generate a measurement value responsive to the voltage signal and the clock signal;
adjust a threshold level for the measurement value from a first threshold to a second threshold, where the second threshold level corresponds to a target voltage level;
provide, to the clock distribution network, a non-violation signal responsive to the measurement value reaching the second threshold.

16. A processor comprising a circuit according to claim 15.

17. The processor of claim 16, comprising a central processor unit or a graphics processor unit.

18. A system comprising:
the circuitry of claim 15, implemented in at least one packaged chip;
at least one system component; and
a board,
wherein the at least one packaged chip and the at least one system component are assembled on the board.

19. A chip-containing product comprising the system of claim 18 assembled on a further board with at least one other product component.

20. A non-transitory computer-readable medium to store computer-readable code for fabrication of the circuitry for providing a clock signal to a sub-system of a processor of claim 18.
